(19) United States
(12) Patent Application Publication
(10) Pub. No.: US 2012/0083064 A1
(43) Pub. Date: Apr. 5, 2012

(54) Process for solar cell module edge sealing

(75) Inventors: Hsieh-Hsin Yeh, Sanchong City (TW); Chi Lai Lee, PingZhen City (TW); Hsuan-Ping Chen, Kaohsiung County (TW)

(73) Assignee: DuPont Apollo Ltd.

(21) Appl. No.: 13/137,624

(22) Filed: Aug. 30, 2011

Related U.S. Application Data
(60) Provisional application No. 61/388,299, filed on Sep. 30, 2010.

(51) Int. Cl. H01L 31/18

(52) U.S. Cl. 438/64; 257/E31.117

(57) ABSTRACT

A new process of edge sealing for solar cell modules is described. The process comprises coating a waterproof material on the edge of the solar cell module to form a U-like shaped edge sealing which can achieve the function of shock absorber.

### FIELD OF THE INVENTION

The present invention relates to the field of thin film solar cells. Particularly, the present invention discloses a process of edge sealing for solar cell modules.

### BACKGROUND OF THE INVENTION

Current processes for edge sealing solar cell modules comprise three main steps: edge coating, gasket installation and framing. In the edge coating step, hot-melt rubber is usually used as a coating material. The rubber is heated to about 190° C. and then is coated by a dispenser on the edge of the solar cell module to form a L-shape coating. The L-shape coating is for sealing the gap between the back sheet and glass of the solar cell module to avoid the permeation of vapor or water into the solar cell module, which can cause the decrease of power of the solar cell module.

In the gasket installation step, a gasket is installed on the solar cell module including the L-shape coating. The gasket is U-shaped and is formed by injection molding of the material selected from ethylene propylene diene monomer (EPDM), 1,3-butadiene or polystyrene (PS). The gasket functions as a buffer or shock absorber between the solar cell module and the frame.

In the framing step, the solar cell module is encapsulated by a frame. The frame mainly provides the mechanical strength to support the solar cell module.

EP 1418627 A2 and US 2005/0115603 A1 provide processes of edge sealing of solar cell modules which can ensure waterproofing. In both cases, the waterproof material is added in the gasket. The solar cell module is encapsulated in the gasket and then can be encapsulated in an aluminum frame.

However, there are too many steps in the typical process or in the processes of the prior art references. In addition, the costs of the materials are high. Thus, it is necessary to seek a simple, cheap and highly reproducible process for edge sealing for solar cell modules.

### SUMMARY OF THE INVENTION

In view of the problems described above, the present invention provides a process for the edge sealing of a solar cell module comprising coating a waterproof material on the edge of the solar cell module to form a U-like shaped edge sealing, wherein the U-like shaped edge sealing has the efficacy of shock absorption.

### BRIEF DESCRIPTION OF THE DRAWINGS

FIG. 1 shows the traditional L-shaped edge sealing and the gasket.

FIG. 2 shows the U-like shaped edge sealing of the present invention.

### DETAILED DESCRIPTION OF THE INVENTION

Features from different embodiments described below are examples of the elements recited in the claims and can be combined together into one embodiment without departing from the scope of the claims.

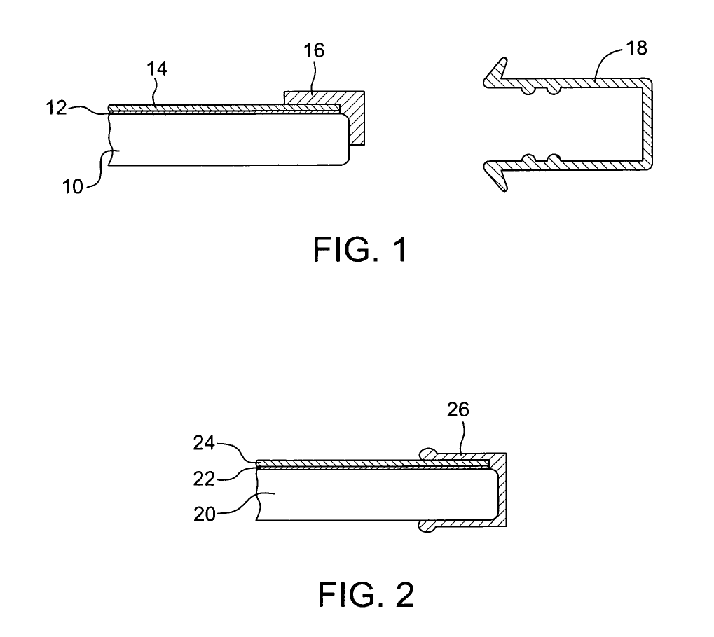

As shown in FIG. 1, a conventional solar cell module mainly comprises substrate 10, a solar cell 12, and an encapsulant (not shown), such as ethylene vinyl acetate (EVA) or polyvinyl butyral (PVB) and a back protection layer 14. In the conventional process of the edge sealing, L-shape rubber 16 is coated on the edge of the solar cell module. Then a gasket 18 is installed on the solar cell module.

The present invention provides a novel process for the edge sealing of a solar cell module. Specifically, the process includes coating a waterproof material on the edge of the solar cell module to form a U-like shaped edge sealing. The U-like shaped edge sealing can be coated by using a modifying edge sealing dispenser. Because the U-like shaped edge sealing of the present invention can function as a gasket to absorb shock and provide stability, the typical gasket installation step can be eliminated. Thus, in the present invention, fewer steps are needed and fewer materials are used for sealing.

The needed coating temperature in the present invention can range from 140 to 220° C. Preferably, the temperature is from 160 to 200° C.

The sealing material can be selected from the group consisting of rubber, silicone, a/b mixing type glue and the combination thereof. Preferably, the sealing material is synthetic rubber. Optionally, additives such as polyethylene (PE), polypropylene (PP), carbon black, organic fiber, inorganic fiber or the combination thereof can be added to the sealing material for coating.

By applying the present invention, a simple process for the edge sealing of a solar cell module with lower total costs can be achieved.

### EXAMPLE

An example of the present invention will be described. The example illustrates a preferable embodiment of the present invention, and the present invention is not limited to the example.

### Example 1

The solar cell module (for example a superstrate type solar cell), which can be illustrated by FIG. 2, comprises substrate 20, a solar cell 22, and an encapsulant (such as ethylene vinyl acetate or polyvinyl butyral, not shown) and a back protection layer 24. In the process of the edge sealing of the solar cell module, a waterproof material comprising synthetic rubber is heated to 160 to 200° C., and coated on the solar cell module to form a U-like shaped sealing 26 by using a modifying edge sealing dispenser. Then the solar cell module is encapsulated by a frame, an aluminum frame for example.

What is claimed is:

1. A process for the edge sealing of a solar cell module comprising coating a waterproof material on the edge of the solar cell module to form a U-like shaped edge sealing, wherein the U-like shaped edge sealing has the efficacy of shock absorption.

2. The process according to claim 1, wherein the waterproof material is selected from the group consisting of rubber, silicone, a/b mixing type glue and the combination thereof.

3. The process according to claim 2, wherein the waterproof material is synthetic rubber.

4. The process according to claim 1, wherein the waterproof material comprises an additive.

5. The process according to claim 4, wherein the additive is selected from the group consisting of polyethylene (PE), polypropylene (PP), carbon black, organic fiber, inorganic fiber and the combination thereof.

6. The process according to claim 1, wherein the coating step is conducted at a temperature in the range of 160 to 200° C.
